(19) United States
(12) Patent Application Publication
(10) Pub. No.: US 2009/0008623 A1
(43) Pub. Date: Jan. 8, 2009

(54) Methods of fabricating nonvolatile memory device and a nonvolatile memory device

(75) Inventors: Hyun-Seok Lim, Hwaseong-si (KR); In-Sun Park, Suwon-si (KR); Gyu-Hwan Oh, Hwaseong-si (KR); Do-Hyung Kim, Seongnam-si (KR); Shin-Jae Kang, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/216,004

(22) Filed: Jun. 27, 2008

(30) Foreign Application Priority Data
Jul. 3, 2007 (KR) 10-2007-0066613

(51) Int. Cl. H01L 47/00; H01L 21/311

(52) U.S. Cl. 257/4; 438/703; 257/E47.001; 257/E21.249

(57) ABSTRACT

Methods of fabricating a nonvolatile memory device using a resistance material and a nonvolatile memory device are provided. According to example embodiments, a method of fabricating a nonvolatile memory device may include forming at least one semiconductor pattern on a substrate, forming a metal layer on the at least one semiconductor pattern, forming a mixed-phase metal silicide layer, in which at least two phases coexist, by performing at least one heat treatment on the substrate so that the at least one semiconductor pattern may react with the metal layer, and exposing the substrate to an etching gas.

### PRIORITY STATEMENT

This application claims priority under 35 U.S.C. §119 to Korean Patent Application No. 10-2007-0066613, filed on Jul. 3, 2007, in the Korean Intellectual Property Office (KIPO), the entire contents of which are incorporated herein by reference.

### BACKGROUND

1. Field

Example embodiments relate to methods of fabricating a nonvolatile memory device using a resistance material and a nonvolatile memory device.

2. Description of the Related Art

Examples of nonvolatile memory devices using a resistance material may include a Phase change Random Access Memory (PRAM) device, a Resistive Random Access Memory (RRAM) device, and a Magnetic Random Access Memory (MRAM) device. Such nonvolatile memory devices using a resistance material may store data by variations in the state of a phase change material, e.g., a chalcogenide alloy, variations in the resistance of a variable resistor, or variations in the resistance of a magnetic tunnel junction (MTJ) thin film with respect to the magnetization of a ferromagnetic material, whereas Dynamic Random Access Memory (DRAM) devices or flash memory devices may store data using charge.

For example, PRAM devices define a crystalline phase of a phase change material as a set state or a logic value of 0 and define the amorphous phase of a phase change material as a reset state or a logic value of 1 in consideration of the fact that a phase change material has lower resistance in the crystalline phase and has higher resistance in the amorphous state. In the case of PRAM devices, a write pulse, e.g., a set pulse and/or a reset pulse, may be provided to a phase change material, and data may be written to the phase change material with joule heat generated by the write pulse. For example, PRAM devices may apply a write pulse, e.g., a set pulse and/or a reset pulse, to phase change materials and write data to the phase change materials using joule heat generated by the write pulse. PRAM devices may write a logic value of 1 to phase change materials by heating the phase change materials to their melting point or higher using a reset pulse and quickly cooling the phase change materials so that the phase change materials become amorphous. PRAM devices may write a logic value of 0 to phase change materials by heating the phase change materials to a temperature between the crystallization temperature and the melting point using a set pulse, and then maintaining the temperature of the phase change materials for a given amount of time so that the phase change materials may become crystalline.

One of the critical issues associated with the integration of PRAM devices may be to reduce the number of write pulses necessary for a write operation. Various methods that involve, for example, scaling up or down the size of lower electrode contacts that contact phase change materials or doping the phase change materials with nitrogen, have been suggested. However, applying these methods to the fabrication of nonvolatile memory devices may not be easy. In addition, these methods may result in various defects, and thus may deteriorate the reliability of nonvolatile memory devices.

### SUMMARY

Example embodiments provide methods of fabricating a nonvolatile memory device which contributes to the improvement of reliability. Example embodiments also provide a nonvolatile memory device. However, example embodiments are not restricted to the ones set forth herein. Example embodiments will become apparent to one of daily skill in the art to which example embodiments pertain by referencing the detailed description of example embodiments given below.

According to example embodiments, a method of fabricating a nonvolatile memory device may include forming at least one semiconductor pattern on a substrate, forming a metal layer on the at least one semiconductor pattern, forming a mixed-phase metal silicide layer, in which at least two phases coexist, by performing at least one heat treatment on the substrate so that the at least one semiconductor pattern may react with the metal layer, and exposing the substrate to an etching gas.

According to example embodiments, a method of fabricating a nonvolatile memory device may include forming an insulation layer pattern including at least one opening on a substrate, forming a vertical cell diode in the at least one opening, forming a mixed-phase metal silicide layer in which at least two phases coexist on the vertical cell diode, forming at least one spacer in at least one aperture and on the mixed-phase metal silicide layer, and forming a lower electrode contact in the at least one aperture so that the lower electrode contact may be surrounded by the at least one spacer. The method may further include forming a second insulation layer pattern including at least one contact hole on the insulation layer pattern before forming the at least one spacer and after forming the mixed-phase metal silicide layer. The at least one aperture may be at least one opening or at least one contact hole.

According to example embodiments, a nonvolatile memory device may include an insulation layer pattern including at least one opening on a substrate, a vertical cell diode in the at least one opening, a mixed-phase metal silicide layer, in which at least two phases coexist, on the vertical cell diode, at least one spacer in at least one aperture and on the mixed-phase metal silicide layer, and a lower electrode contact in the at least one aperture and surrounded by the at least one spacer. The method may further include a second insulation layer pattern on the insulation layer pattern including at least one contact hole. The at least one aperture may be at least one opening or at least one contact hole.

### BRIEF DESCRIPTION OF THE DRAWINGS

Example embodiments will be more clearly understood from the following detailed description taken in conjunction with the accompanying drawings. FIGS. 1-18B represent non-limiting, example embodiments as described herein.

FIGS. 1 and 2 are a block diagram and a circuit diagram, respectively, of a nonvolatile memory device according to example embodiments;

FIGS. 3A-16 are diagrams for explaining a method of fabricating a nonvolatile memory device according to example embodiments;

FIG. 17 is a diagram showing experimental results of metal silicide layers obtained under various heat treatment conditions;

FIG. 18A shows the surface of a mixed-phase metal silicide layer after an exposure to an etching gas; and

FIG. 18B shows the surface of a single-phase metal silicide layer after an exposure to an etching gas.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. In particular, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF EXAMPLE EMBODIMENTS

Example embodiments will now be described more fully with reference to the accompanying drawings, in which example embodiments are shown. Example embodiments may, however, be embodied in many different forms and should not be construed as being limited to the embodiments set forth herein. Rather, these embodiments are provided so that this disclosure will be thorough and complete, and will fully convey the concept of example embodiments to those skilled in the art.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers refer to like elements throughout. As used herein the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

The terminology used herein is for the purpose of describing particular embodiments only and is not intended to be limiting of example embodiments. As used herein, the singular forms a, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which example embodiments belong. It should be further understood that terms, such as those defined in commonly used dictionaries, should be interpreted as having a meaning that is consistent with their meaning in the context of the relevant art and will not be interpreted in an idealized or overly formal sense unless expressly so defined herein.

Furthermore, relative terms such as “below,” “beneath,” or “lower,” “above,” and “upper” may be used herein to describe one element's relationship to another element as illustrated in the accompanying drawings. It will be understood that relative terms are intended to encompass different orientations of the device in addition to the orientation depicted in the accompanying drawings. For example, if the device in the accompanying drawings is turned over, elements described as being on the “lower” side of other elements would then be oriented on “upper” sides of the other elements. Similarly, if the device in one of the figures is turned over, elements described as “below” or “beneath” other elements would then be oriented “above” the other elements. Therefore, the exemplary terms “below” and “beneath” can, therefore, encompass both an orientation of above and below.

Example embodiments will hereinafter be described in detail, taking a Phase change Random Access Memory (PRAM) as an example. However, example embodiments may be applied to all nonvolatile memory devices using a resistance material, e.g., a Resistive Random Access Memory (RRAM) or a Magnetic Random Access Memory (MRAM).

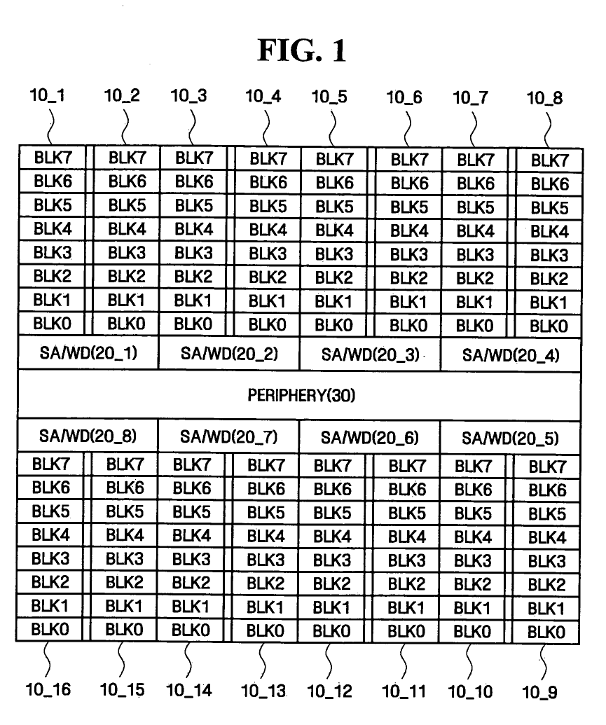

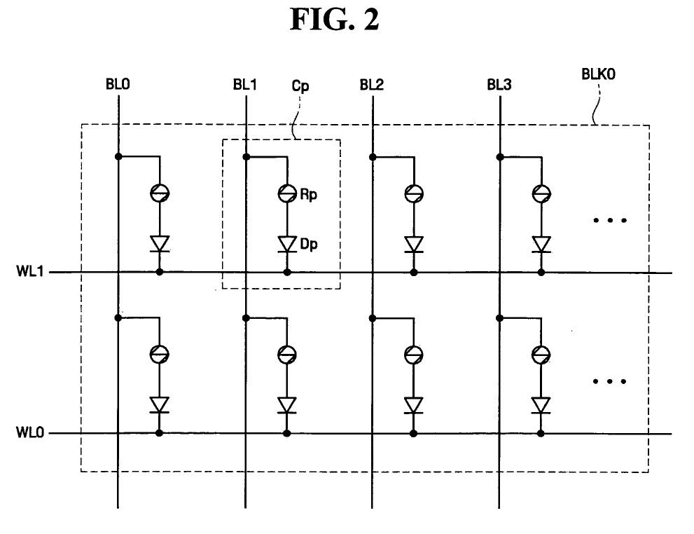

FIGS. 1 and 2 are a block diagram and a circuit diagram, respectively, of a nonvolatile memory device according to example embodiments. The nonvolatile memory device may include 16 memory banks. However, example embodiments may not be restricted to this. For clarity, FIG. 2 illustrates only one memory block, e.g., a first memory block BLK0.

Referring to FIG. 1, the nonvolatile memory device may include a plurality of memory banks 10_1 through 10_16, a plurality of sense amplifiers/write drivers 20_1 through 20_8, and a peripheral circuit region 30. Each of the memory banks 10_1 through 10_16 may include a plurality of memory blocks BLK0 through BLK7, and each of the memory blocks BLK0 through BLK7 may include a plurality of nonvolatile memory cells which are arranged in a matrix. Each of the memory banks 10_1 through 10_16 may include 8 memory blocks. However, example embodiments may not be restricted to this.

A row decoder (not shown) and a column decoder (not shown) may be provided for each of the memory banks 10_1 through 10_16 for designating a row and a column of nonvolatile memory cells to/from which data is to be written/read. The sense amplifiers/write drivers 20_1 through 20_8 may be arranged in such a manner that a sense amplifier/write driver may correspond to two memory banks, and may perform a read operation and a write operation on the two memory banks. However, example embodiments may not be restricted to this.

For example, the sense amplifiers/write drivers 20_1 through 20_8 may be arranged in such a manner that a sense amplifier/write driver may correspond to one or four memory banks. The row decoder, the column decoder, a plurality of logic circuit blocks for driving the sense amplifiers/write drivers 20_1 through 20_8, and a voltage generation module are disposed in the peripheral circuit region 30.

Referring to FIG. 2, the memory block BLK0 may include a plurality of nonvolatile memory cells Cp, a plurality of bitlines BL0 through BL3 and a plurality of wordlines WL0 and WL1. The nonvolatile memory cells Cp may be respectively disposed at the intersections between the bitlines BL0 through BL3 and the wordlines WL0 and WL1. The nonvolatile memory cells Cp may shift between a crystalline phase and an amorphous phase in response to a penetration current applied thereto. Each of the nonvolatile memory cells Cp may include a phase change element Rp whose resistance varies according to whether a corresponding nonvolatile memory cell Cp is in the crystalline phase or in the amorphous phase, and a vertical cell diode Dp which controls a penetration current that flows into the phase change element Rp.

Each of the phase change elements Rp of the nonvolatile memory cells Cp may include a compound of two elements, e.g., GaSb, InSb, InSe, Sb₂Te₃ and/or GeTe, a compound of three elements, e.g., GeSbTe, GaSeTe, InSbTe, SnSb₂Te₄ and/or InSbGe, or a compound of four elements, e.g., AgInSbTe, (GeSn)SbTe, GeSb(SeTe) and/or Te₈₁Ge₁₅Sb₂S₂. For example, each of the phase change elements Rp of the nonvolatile memory cells Cp may include a compound of Ge, Sb, and Te, e.g., GeSbTe. Referring to FIG. 2, each of the phase change elements Rp of the nonvolatile memory cells Cp may be coupled to one of the bitlines BL0 through BL3, and each of the vertical cell diodes Dp of the nonvolatile memory cells Cp may be coupled to one of the wordlines WL0 and WL1. However, example embodiments may not be restricted to this. For example, each of the phase change elements Rp of the nonvolatile memory cells Cp may be coupled to one of the wordlines WL0 and WL1, and each of the vertical cell diodes Dp of the nonvolatile memory cells Cp may be coupled to one of the bitlines BL0 through BL3.

An operation of the nonvolatile memory device illustrated in FIG. 1 will hereinafter be described in detail with reference to FIG. 2. The nonvolatile memory device illustrated in FIG. 1 may perform a write operation by heating the phase change elements Rp to the melting point Tm of the phase change elements Rp or higher, and quickly cooling the phase change elements Rp so that the phase change elements Rp change to their amorphous state corresponding to a logic level of 1. Alternatively, the nonvolatile memory device may perform a write operation by heating the phase change elements Rp to a temperature between a crystallization temperature Tx of the phase change elements Rp and the melting point Tm and then maintaining the temperature of the phase change elements Rp for a predefined or given amount of time so that the phase change elements Rp change to their crystalline state corresponding to a logic level of 0. In order to change the phase of the phase change elements Rp, relatively high write currents may be transmitted through the phase change elements Rp. For example, a write current for resetting the phase change elements Rp may be about 1 mA, and a write current for setting the phase change elements Rp may be about 0.6 mA-about 0.7 mA. These write currents may be provided by a write circuit (not shown), and may be grounded, passing through the bitlines BL0 through BL3 and the vertical cell diodes Dp.

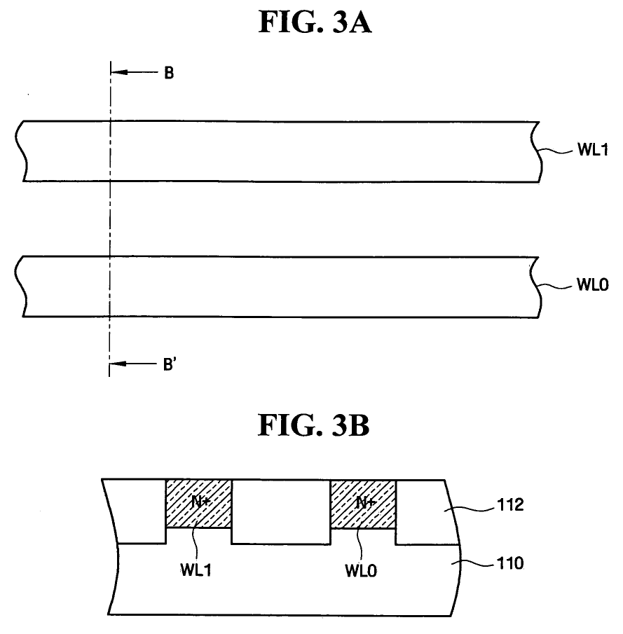

A method of fabricating a nonvolatile memory device according to example embodiments will hereinafter be described in detail with reference to FIGS. 3A through 12B. FIGS. 3B, 4B, 11B, and 12B are cross-sectional views taken along lines B-B′ of FIGS. 3A, 4A, 11A, and 12A, respectively. Referring to FIGS. 3A and 3B, a plurality of isolation regions 112 may be formed in a substrate 110 of a first conductivity type (e.g., a p-type), thereby defining a plurality of active regions. The active regions may extend in a first direction parallel with one another. A plurality of wordlines WL0 and WL1 may be formed by implanting impurities of a second conductivity type (e.g., n-type) into the active regions. The substrate 110 may be a silicon substrate, a silicon-on-insulator (SOI) substrate, a gallium asbestos substrate and/or a silicon germanium substrate.

The formation of the wordlines WL0 and WL1, however, may not be restricted to that set forth herein. For example, the wordlines WL0 and WL1 may be formed using an epitaxial growth method. For example, a mold layer pattern including a plurality of openings may be formed on the substrate 110 so that the surface of the substrate 110 may be partially exposed through the openings of the mold layer pattern. Thereafter, an epitaxial layer may be formed in the openings of the mold layer pattern using a selective epitaxial growth (SEG) method and/or a solid phase epitaxial (SPE) growth method. Thereafter, impurity ions of the second conductivity type may be injected into the substrate 110, thereby completing the formation of the wordlines WL0 and WL1. If the substrate 110 is doped in situ with impurities during an SEG operation and/or an SPE growth operation, the injection of impurity ions into the substrate 110 may be skipped.

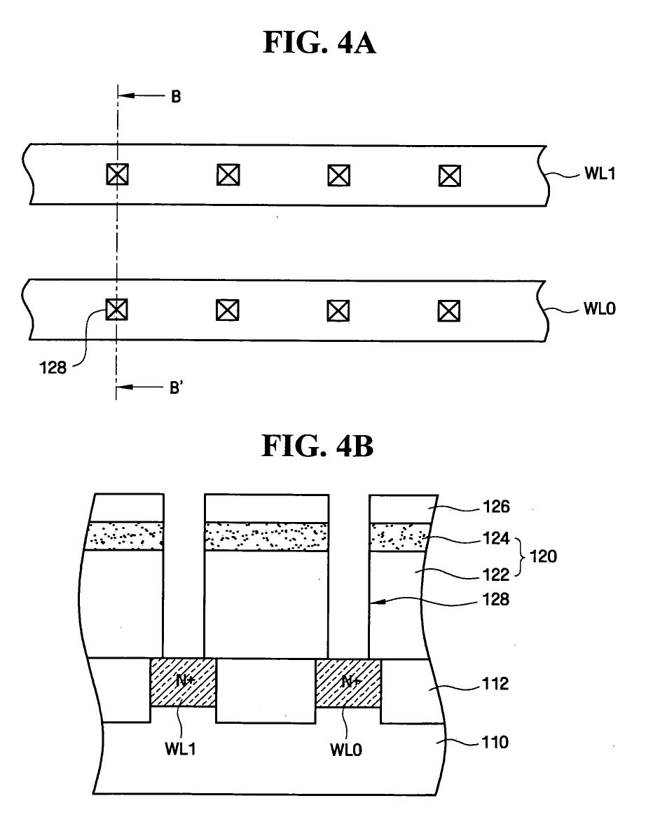

Referring to FIGS. 4A and 4B, a lower insulation layer pattern 120 and a sacrificial layer pattern 126 including a plurality of openings 128 may be formed on the substrate 110 so that the surface of the substrate 110 may be partially exposed through the openings 128. For example, the lower insulation layer pattern 120 may include a first lower insulation layer pattern 122 and a second lower insulation layer pattern 124. The sacrificial layer pattern 126 may be formed of a material having etching selectivity with respect to the second lower insulation layer pattern 124, and the second lower insulation layer pattern 124 may be formed of a material having etching selectivity with respect to the first lower insulation layer pattern 122. For example, the first lower insulation layer pattern 122 and the sacrificial layer pattern 126 may include a silicon oxide layer (SiO₂), and the second lower insulation layer pattern 124 may include a silicon oxynitride layer (SiON) and/or a silicon nitride layer (SiN).

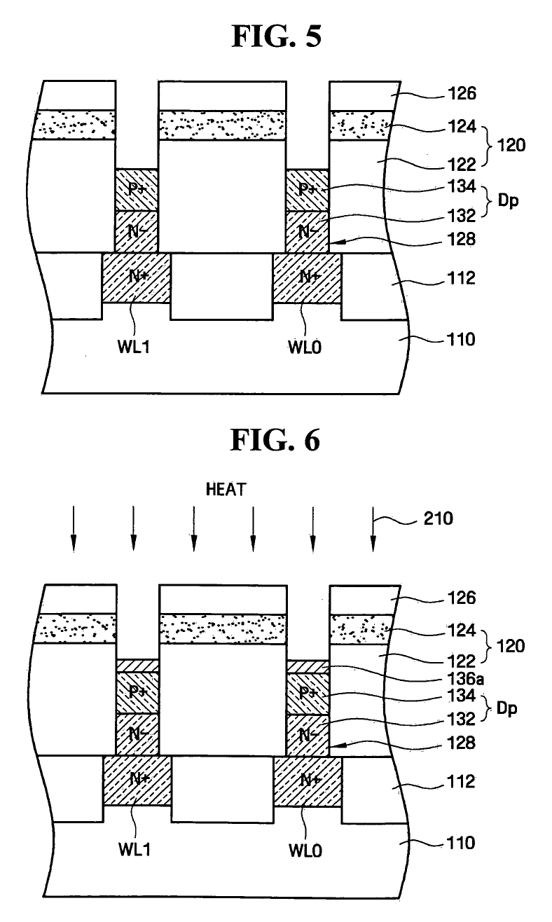

Referring to FIG. 5, a plurality of first semiconductor patterns 132 and a plurality of second semiconductor patterns 134 may be respectively formed in the openings 128, thereby forming a plurality of vertical cell diodes Dp. The first semiconductor patterns 132 and the second semiconductor patterns 134 may be formed in various manners. For example, the first semiconductor patterns 132 and the second semiconductor patterns 134 may be formed using an epitaxial growth method. For example, the first semiconductor patterns 132 may be formed using, as seed layers, the wordlines WL0 and WL1 which are exposed through the openings 128, and the second semiconductor patterns 134 may be formed using the first semiconductor patterns 132 as seed layers. If the wordlines WL0 and WL1 are monocrystalline, the first semiconductor patterns 132 and the second semiconductor patterns 134 may also be monocrystalline.

Alternatively, the first semiconductor patterns 132 and the second semiconductor patterns 134 may be formed using an SPE growth method. Thereafter, impurity ions of the second conductivity type may be injected into each of the first semiconductor patterns 132, and impurity ions of the first conductivity type may be injected into each of the second semiconductor patterns 134. If the first semiconductor patterns 132 and the second semiconductor patterns 134 are doped in situ with impurities during an SEG operation or an SPE growth operation, the injection of impurity ions into the first semiconductor patterns 132 and the second semiconductor patterns 134 may be skipped.

In order to reduce a leakage current that flows through a reverse-biased vertical cell diode upon applying a reverse bias to the cell diodes Dp, the first semiconductor patterns 132 may have a lower impurity concentration than the wordlines WL0 and W11, and the second semiconductor patterns 134 may have a higher impurity concentration than the first semiconductor patterns 132. The reverse bias may be applied to the vertical cell diodes Dp of PRAM cells that are not chosen during a write or read operation.

Referring to FIG. 6, a plurality of mixed-phase metal silicide layers 136a, in which at least two phases coexist, may be formed on the respective vertical cell diodes Dp. The mixed-phase metal silicide layers 136a may serve as ohmic layers for the respective vertical cell diodes Dp. For example, a plurality of metal layers may be formed on the respective vertical cell diodes Dp. The metal layers may include at least one of Co, Ni, and Ti. In example embodiments, the metal layers include Co. The metal layers may be formed using a physical vapor deposition (PVD) method, a chemical vapor deposition (CVD) method and/or an atomic layer deposition (ALD) method. The thickness of the metal layers may be determined in consideration of the thickness of silicon that will be consumed during a first heat treatment (not shown) and a second heat treatment 210. A plurality of capping layers may be formed on the respective metal layers for morphology improvement. The capping layers may include at least one of TiN, SiON, SiN, and SiO₂.

Thereafter, the first heat treatment may be performed on the substrate 110 so that the substrate 110 may react with the metal layers. For example, the first heat treatment may be performed at a temperature of about 460° C.-about 540° C. The first heat treatment may be performed using a rapid thermal annealing (RTA) method. As a result of the first heat treatment, a plurality of pre-metal silicide layers may be formed on the respective metal layers. The pre-metal silicide layers may have a CoSi phase.

The capping layers and portions of the metal layers that have not reacted with the substrate 110 may be removed. The capping layers and the portions of the metal layers that have not reacted with the substrate 110 may be removed separately. Alternatively, the capping layers and the portions of the metal layers that have not reacted with the substrate 110 may be removed at the same time. For example, if the metal layers include Co and the capping layers include TiN, the capping layer and the portions of the metal layers that have not reacted with the substrate 110 may be removed at the same time using sulfuric acid.

The second heat treatment 210 may be performed at a higher temperature than the first heat treatment. For example, the second heat treatment 210 may be performed at a temperature of about 540° C.-about 600° C. The second heat treatment 210 may also be performed using an RTA method. As a result of the second heat treatment 210, the Spre-metal silicide layers may be transformed into the mixed-phase metal silicide layers 136a. For example, the CoSi phase and a CoSi₂ phase may both coexist in the mixed-phase metal silicide layers 136a. If the second heat treatment is performed at a temperature of about 700° C. or higher, e.g., at a temperature of about 750° C.-about 850° C., single-phase metal silicide layers, instead of the mixed-phase metal silicide layers 136a, may be formed. The single-phase metal silicide layers may have the CoSi₂ phase. The mixed-phase metal silicide layers 136a may have a higher resistance than the single-phase metal silicide layers. However, the mixed-phase metal silicide layers 136a may be more durable than the single-phase metal silicide layers and are thus may be less likely than the single-phase metal silicide layers to be damaged by an etching gas.

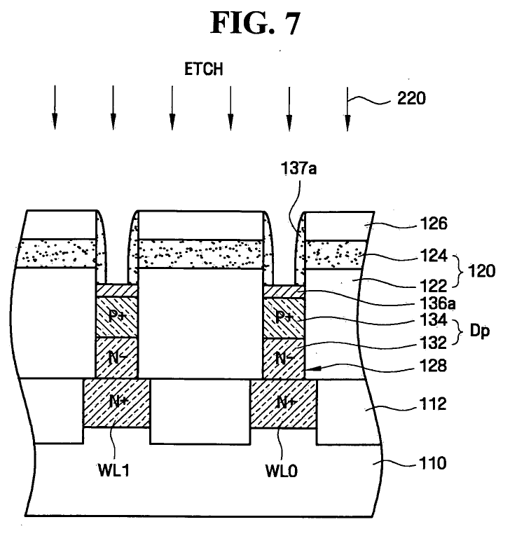

Referring to FIG. 7, a plurality of spacers 137a may be formed in the respective openings 128. The spacers 137a may be disposed on the respective mixed-phase metal silicide layers 136a. For example, the spacers 137a may be formed by forming a plurality of insulation layers for spacers on the respective mixed-phase metal silicide layers 136a and etching back the insulation layers for spacers, as indicated by reference numeral 220. The spacers 137a may be formed of a material having etching selectivity with respect to the sacrificial layer pattern 126. For example, if the sacrificial layer pattern 126 includes a silicon oxide layer (SiO₂), the spacers 137a may include a silicon oxynitride layer (SiON) and/or a silicon nitride layer (SiN).

During the etch-back of the insulation layers for spacers, the insulation layers for spacers may be over-etched even after the mixed-phase metal silicide layers 136 are exposed. For example, assume that CH₂H₂+CHF₃ is used as an etching gas during the etch-back of the insulation layers for spacers. Single-phase metal silicide layers may be more easily damaged by CH₂H₂+CHF₃ and thus may result in voids. On the other hand, the mixed-phase metal silicide layers 136a may be more durable than single-phase metal silicide layers and may thus be less likely to be damaged even when the insulation layers for spacers are over-etched. Therefore, the reliability of a nonvolatile memory device may be enhanced.

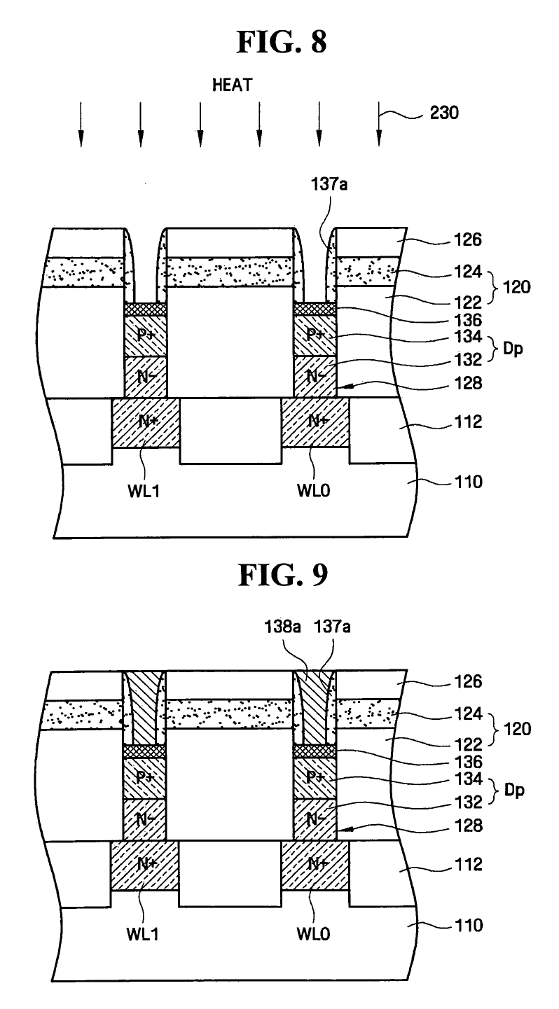

Referring to FIG. 8, a third heat treatment 230 may be performed on the substrate 110 so that the mixed-phase metal silicide layers 136a may be transformed into single-phase metal silicide layers 136. The third heat treatment 230 may be performed at a temperature of about 750° C.-about 850° C. As a result of the third heat treatment 230, the mixed-phase metal silicide layers 136a having both the CoSi phase and the CoSi₂ phase may be transformed into the single-phase metal silicide layers 136 having the CoSi₂ phase. The single-phase metal silicide layers 136 may have a relatively low resistance and may thus improve the operating properties of a nonvolatile memory device.

The third heat treatment 230 may be optional. Thus, a nonvolatile memory device obtained using a method that involves the third heat treatment 230 may include mixed-phase metal silicide layers, whereas a nonvolatile memory device obtained using a method that does not involve the third heat treatment 230 may include mixed-phase metal silicide layers. Even if the third heat treatment 230 is skipped, the mixed-phase metal silicide layers 136a may be transformed into the single-phase metal silicide layers 136 if subsequent processes include performing a heat treatment on the substrate 110 at a temperature of about 750° C. or higher.

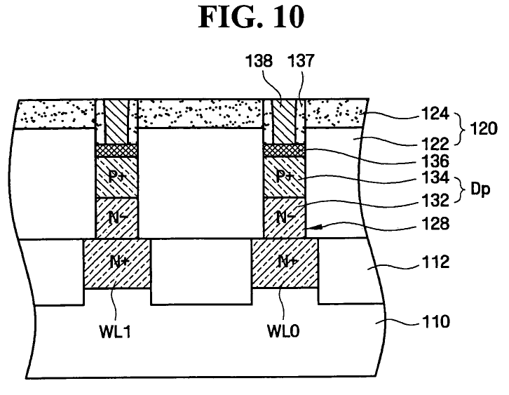

Referring to FIG. 9, a plurality of lower electrode contacts 138a may be formed in the respective openings 128, and may be surrounded by the respective pairs of spacers 137a. For example, the lower electrode contacts 138a may be formed by forming a conductive layer for contacts on the sacrificial layer pattern 126 and planarizing the conductive layer until the top surface of the sacrificial layer pattern 126 may be exposed. The lower electrode contacts 138a may include a titanium nitride layer (TiN), a titanium aluminum nitride layer (TiAlN), a tantalum nitride layer (TaN), a tungsten nitride layer (WN), a molybdenum nitride layer (MoN), a niobium nitride layer (NbN), a titanium silicon nitride layer (TiSiN), a titanium boron nitride layer (TiBN), a zirconium silicon nitride layer (ZrSiN), a tungsten silicon nitride layer (WSiN), a tungsten boron nitride layer (WBN), a zirconium aluminum nitride layer (ZrAlN), a molybdenum aluminum nitride layer (MoAlN), a tantalum silicon nitride layer (TaSiN), a tantalum aluminum nitride layer (TaAlN), a titanium tungsten layer (TiW), a titanium aluminum layer (TiAl), a titanium oxynitride layer (TiON), a titanium aluminum oxynitride layer (TiAlON), a tungsten oxynitride layer (WON) and/or a tantalum oxynitride layer (TaON).

Referring to FIG. 10, the second lower insulation layer pattern 124 may be exposed by removing the sacrificial layer pattern 126 of FIG. 7. As a result, the lower electrode contacts 138a and the spacers 137a may protrude beyond the top surface of the second lower insulation layer pattern 124. Thereafter, the lower electrode contacts 138a and the spacers 137 may be planarized using the second lower insulation layer pattern 124 as a stopper. Accordingly, a plurality of lower electrode contacts 138 may be formed on the respective vertical cell diodes Dp. The top surfaces of the lower electrode contacts 138 may be substantially on a level with the top surface of the second lower insulation layer pattern 124. The area of the top surfaces may be less than the cross-sectional area of the openings 128 because of the spacers 137. The lower electrode contacts 138 may be self-aligned with the respective vertical cell diodes Dp by the openings 128.

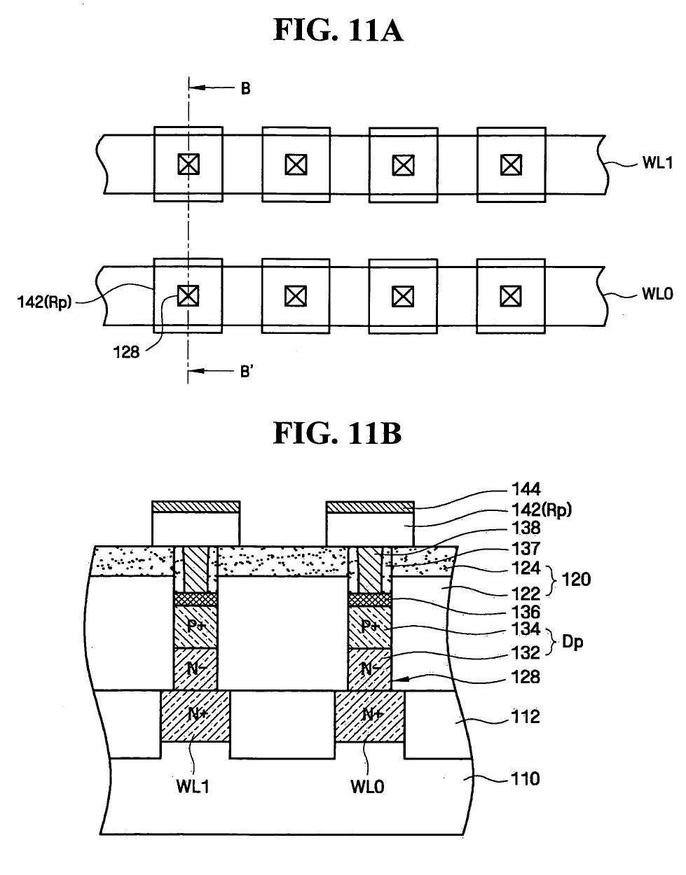

Referring to FIGS. 11A and 11B, a plurality of phase-change-material patterns 142 and a plurality of upper electrode contacts 144 may be formed on the lower electrode contacts 138. For example, the phase-change-material patterns 142 and the upper electrode contacts 144 may be formed by sequentially forming a phase change material layer and a conductive layer for upper contacts on the substrate 110, and patterning the phase change material layer and the conductive layer. The phase change material layer may be formed using a physical vapor deposition method, e.g., sputtering, which may provide undesirable step coverage. However, the phase change material layer may have a uniform thickness across the entire substrate 110 because the surface of the substrate 110 may be flat.

The phase-change-material patterns 142 may be formed of a compound of two elements, e.g., GaSb, InSb, InSe, Sb₂Te₃ and/or GeTe, a compound of three elements, e.g., GeSbTe, GaSeTe, InSbTe, SnSb₂Te₄ and/or InSbGe, or a compound of four elements, e.g., AgInSbTe, (GeSn)SbTe, GeSb(SeTe) and/or Te₈₁Ge₁₅Sb₂S₂. The upper electrode patterns 144 may include a titanium/titanium nitride layer (Ti/TiN).

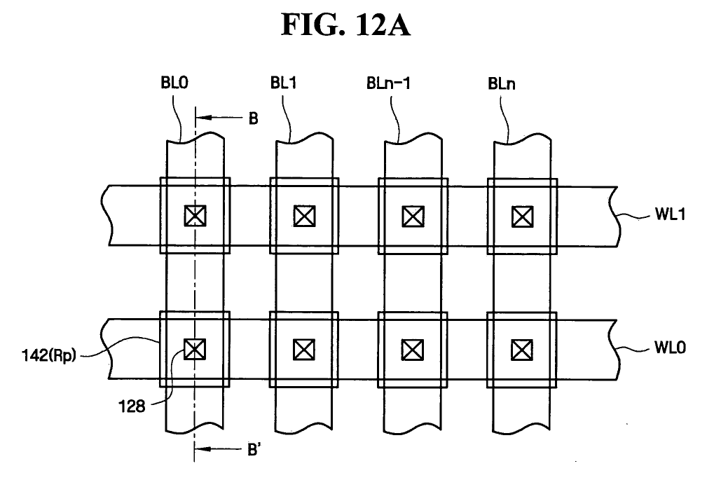

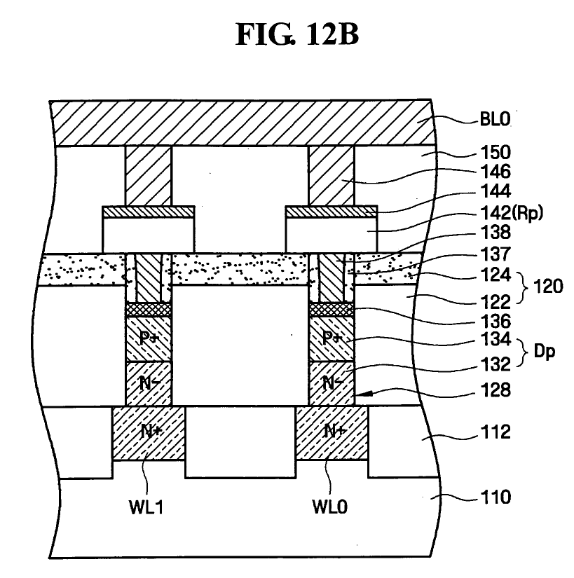

Referring to FIGS. 12A and 12B, an upper insulation layer pattern 150 including a plurality of contact holes may be formed on the substrate 110, and a plurality of line contact plugs 146 may be formed in the respective contact holes. Thereafter, a plurality of bitlines BL0 through BL3 may be formed on the bitline contact plugs 146. The bitlines BL0 through BL3 may extend in a second direction. The bitlines BL0 through BL3 may intersect the wordlines WL0 and WL1.

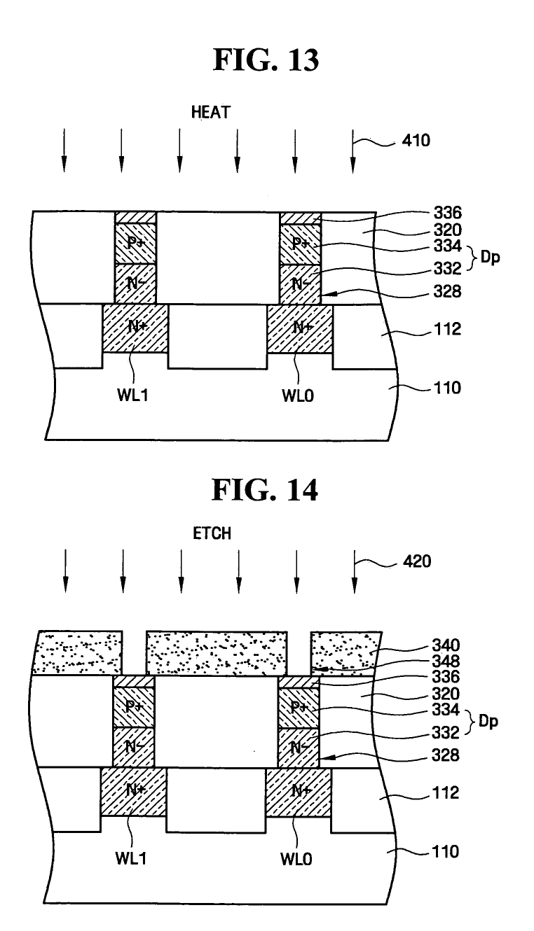

A method of fabricating a nonvolatile memory device according to example embodiments will hereinafter be described in detail with reference to FIGS. 13-16. Example embodiments illustrated in FIGS. 13-16 differ from example embodiments illustrated in FIGS. 3A-12B in that lower electrode contacts are not self-aligned with respective corresponding vertical cell diodes.

Referring to FIG. 13, a plurality of isolation regions 112 may be formed in a substrate 110 of a first conductivity type (e.g., p-type), thereby defining a plurality of active regions. A plurality of wordlines WL1 and WL2 may be formed by implanting impurities of a second conductivity type (e.g., n-type) into the active regions. The wordlines WL1 and WL2 may extend in a first direction. Thereafter, a lower insulation layer pattern 320 including a plurality of openings 328 may be formed on the substrate 110 so that the surface of the substrate 110 may be partially exposed through the openings 328.

Thereafter, a plurality of first semiconductor patterns 332 and a plurality of second semiconductor patterns 334 may be respectively formed in the openings 328, thereby forming a plurality of vertical cell diodes Dp. Thereafter, a plurality of mixed-phase metal silicide layers 336, in which at least two phases coexist, may be formed on the respective cell diodes Dp. A CoSi phase and a CoSi₂ phase may both coexist in the mixed-phase metal silicide layers 336. Formation of the mixed-phase metal silicide layers 336, like the formation of the mixed-phase metal silicide layers 136a of example embodiments illustrated in FIGS. 3A through 12B, may involve forming a metal layer on the vertical cell diodes Dp and performing two heat treatments including first and second heat treatments. The first heat treatment (not shown) may be performed at a temperature of about 460° C.-about 540° C., and the second heat treatment 410 may be performed at a temperature of about 540° C.-about 600° C.

Referring to FIG. 14, an insulation layer pattern 340 including a plurality of contact holes 348 may be formed on the lower insulation layer pattern 320. For example, an insulation layer (not shown) may be formed on the lower insulation layer pattern 320, and the contact holes 348 may be formed by etching the insulation layer. The mixed-phase metal silicide layers 336 may be durable enough not to be damaged by an etching gas used in the etching of the insulation layer.

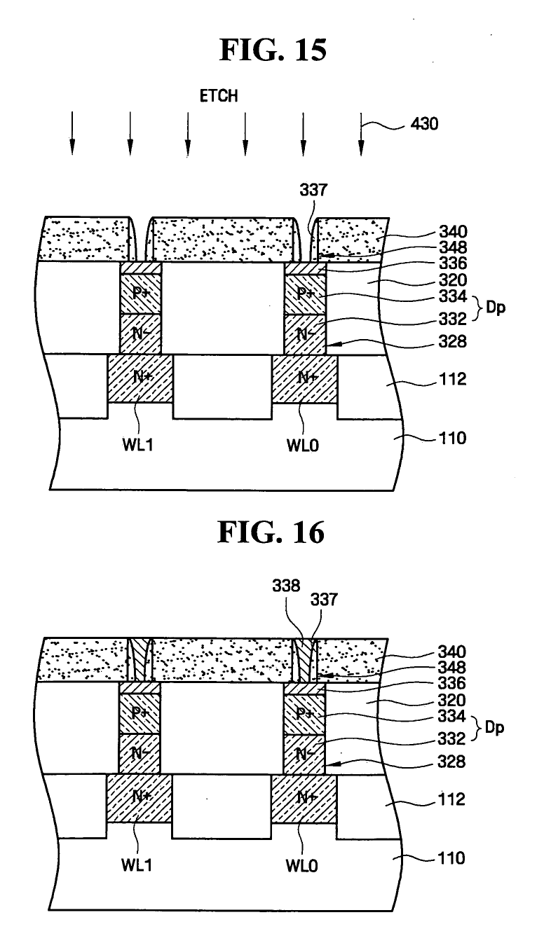

Referring to FIG. 15, a plurality of pairs of spacers 337 may be formed in the respective contact holes 348. The spacers 337 may be disposed on the respective mixed-phase metal silicide layers 336. For example, the spacers 337 may be formed by forming a plurality of insulation layers for spacers in the respective contact holes 348 and etching back the insulation layers for spacers, as indicated by reference numeral 430. The mixed-phase metal silicide layers 336 may be durable enough not to be damaged by an etching gas used in the etch-back of the insulation layers for spacers.

Referring to FIG. 16, a plurality of lower electrode contacts 338 may be formed in the respective contact holes 348 and may be surrounded by the respective pairs of spacers 337. After the formation of the lower electrode contacts 338, a plurality of phase-change-material patterns (not shown) and a plurality of upper electrode contacts (not shown) may be formed on the lower electrode contacts 338, an upper insulation layer pattern (not shown) including a plurality of contact holes (not shown) may be formed on the substrate 110, a plurality of bitline contact plugs (not shown) may be formed in the respective contact holes (not shown), and a plurality of bitlines (not shown) may be formed on the bitline contact plugs (not shown) so that the bitlines (not shown) may extend in a second direction. Example embodiments will hereinafter be described in further detail with reference to experimental examples 1 and 2.

### EXPERIMENTAL EXAMPLE 1

Five experimental groups were used, as follows. The first experimental group may correspond to a metal silicide layer obtained by forming a metal layer (Co) and a capping layer (TiN) on a bulk substrate, performing a first heat treatment at a temperature of about 460° C. and removing the capping layer and portions of the metal layer that have not reacted with the bulk substrate. The second experimental group may correspond to a metal silicide layer obtained by forming a metal layer (Co) and a capping layer (TiN) on a bulk substrate, performing the first heat treatment at a temperature of about 460° C., removing the capping layer and portions of the metal layer that have not reacted with the bulk substrate, and performing a second heat treatment at a temperature of about 600° C. The third experimental group may correspond to a metal silicide layer obtained by forming a metal layer (Co) and a capping layer (TiN) on a bulk substrate, performing the first heat treatment at a temperature of about 460° C., removing the capping layer and portions of the metal layer that have not reacted with the bulk substrate, and performing the second heat treatment at a temperature of about 750° C. The fourth experimental group may correspond to a metal silicide layer obtained by forming a metal layer (Co) and a capping layer (TiN) on a bulk substrate, performing the first heat treatment at a temperature of about 460° C., removing the capping layer and portions of the metal layer that have not reacted with the bulk substrate, and performing the second heat treatment at a temperature of 850° C. The fifth experimental group may correspond to a metal silicide layer obtained by forming a metal layer (Co) and a capping layer (TiN) on a bulk substrate, performing the first heat treatment at a temperature of about 460° C., removing the capping layer and portions of the metal layer that have not reacted with the bulk substrate, and performing the second heat treatment at a temperature of about 900° C.

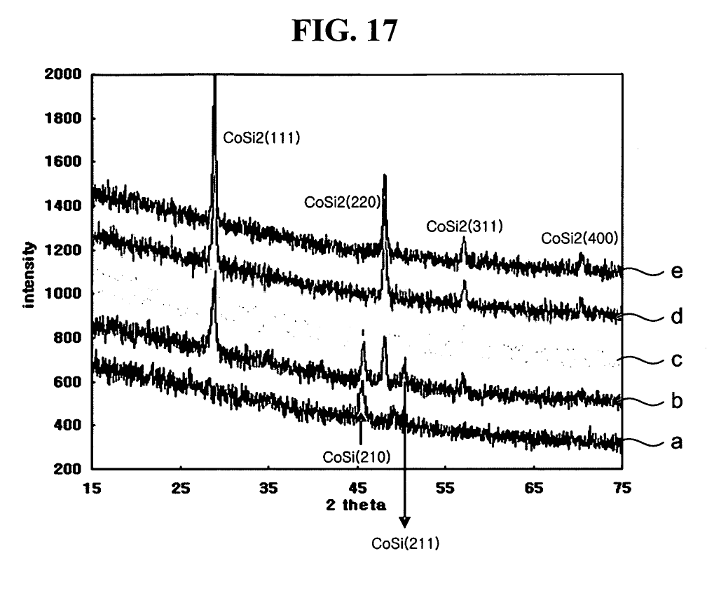

The five experimental groups were analyzed using an X-ray diffractometer (XRD), and the result of the analysis is illustrated in FIG. 17. Referring to FIG. 17, reference characters a through e respectively correspond to the metal silicide layers of the first through fifth experimental groups. The metal silicide layers a and b have a peak corresponding to a CoSi phase. For example, the metal silicide layer b has both the CoSi phase and a CoSi₂ phase. If the second heat treatment is performed at a temperature of about 750° C. or higher, a mixed-phase metal silicide layer, in which the CoSi phase and the CoSi₂ phase coexist, may not be able to be formed.

### EXPERIMENTAL EXAMPLE 2

A comparison group corresponds to a metal silicide layer obtained by forming a metal layer (Co) and a capping layer (TiN) on a bulk substrate, performing a first heat treatment at a temperature of about 460° C., removing the capping layer and portions of the metal layer that have not reacted with the bulk substrate, performing a second heat treatment at a temperature of about 750° C., and performing an etch-back using the same conditions as used in the formation of the spacers 137a of FIG. 7.

An experimental group corresponds to a metal silicide layer obtained by forming a metal layer (Co) and a capping layer (TiN) on a bulk substrate, performing the first heat treatment at a temperature of about 460° C., removing the capping layer and portions of the metal layer that have not reacted with the bulk substrate, performing the second heat treatment at a temperature of about 650° C., and performing an etch-back using the same conditions as used in the formation of the spacers 137a of FIG. 7.

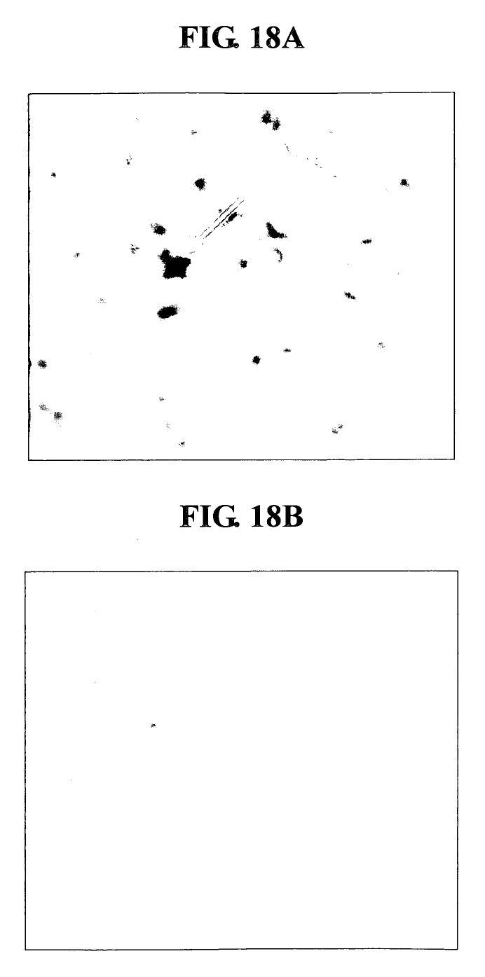

FIGS. 18A and 18B respectively show the surface of the metal silicide layer of the comparison group and the surface of the metal silicide layer of the experimental group. Referring to FIG. 18A, the surface of the metal silicide layer of the comparison group may be damaged, as indicated by the arrows. Referring to FIGS. 18A and 18B, the surface of the metal silicide layer of the experimental group may be less damaged than the surface of the metal silicide layer of the comparison group. As described above, according to example embodiments, the metal silicide layers, which may serve as ohmic layers for vertical cell diodes, may have reduced damages, thus enhancing the reliability of a nonvolatile memory device.

While example embodiments have been particularly shown and described with reference to example embodiments thereof, it will be understood by those of ordinary skill in the art that various changes in form and details may be made therein without departing from the spirit and scope of the following claims.

What is claimed is:

1. A method of fabricating a nonvolatile memory device, the method comprising:
forming at least one semiconductor pattern on a substrate;
forming a metal layer on the at least one semiconductor pattern;
forming at least one mixed-phase metal silicide layer, in which at least two phases coexist, by performing at least one heat treatment on the substrate so that the at least one semiconductor pattern reacts with the metal layer; and
exposing the substrate to an etching gas.

2. The method of claim 1 wherein performing at least one heat treatment on the substrate comprises performing a first heat treatment on the substrate and performing a second heat treatment on the substrate at a higher temperature than the first heat treatment.

3. The method of claim 2, wherein performing the second heat treatment comprises performing the second heat treatment at a temperature of about 540° C.-about 600° C.

4. The method of claim 1, wherein at least two phases are both a CoSi phase and a CoSi₂ phase.

5. The method of claim 1, further comprising:
transforming the mixed-phase metal silicide layer into a single-phase metal silicide layer by performing a third heat treatment on the substrate, after the exposure of the substrate to the etching gas.

6. The method of claim 5, wherein:
forming the mixed-phase metal silicide layer comprises performing a first heat treatment on the substrate and performing a second heat treatment on the substrate at a higher temperature than the first heat treatment; and
transforming the mixed-phase metal silicide layer into the single-phase metal silicide layer comprises performing the third heat treatment at a higher temperature than the second heat treatment.

7. The method of claim 5, wherein:
the mixed-phase metal silicide layer has both a CoSi phase and a CoSi₂ phase; and
the single-phase metal silicide layer has a CoSi₂ phase.

8. A method of fabricating a nonvolatile memory device, comprising:
forming an insulation layer pattern including at least one opening on a substrate;
forming a vertical cell diode in the at least one opening;
forming a mixed-phase metal silicide layer in which at least two phases coexist on the vertical cell diode;
forming at least one spacer in at least one aperture and on the mixed-phase metal silicide layer; and
forming a lower electrode contact in the at least one aperture so that the lower electrode contact is surrounded by the at least one spacer.

9. The method of claim 8, further comprising:
forming a second insulation layer pattern including at least one contact hole on the insulation layer pattern before forming the at least one spacer and after forming the mixed-phase metal silicide layer.

10. The method of claim 8, wherein the at least one aperture is at least one opening.

11. The method of claim 9, wherein the at least one aperture is at least one contact hole.

12. The method of claim 8, wherein forming the mixed-phase metal silicide layer comprises forming a metal layer on the vertical cell diode, performing a first heat treatment on the substrate and performing a second heat treatment on the substrate at a higher temperature than the first heat treatment.

13. The method of claim 12, wherein performing the second heat treatment comprises performing the second heat treatment at a temperature of about 540° C.-about 600° C.

14. The method of claim 8, wherein the mixed-phase metal silicide layer has both a CoSi phase and a CoSi₂ phase.

15. The method of claim 12, further comprising:
transforming the mixed-phase metal silicide layer into a single-phase metal silicide layer by performing a third heat treatment on the substrate, after forming the at least one spacer.

16. The method of claim 15, wherein transforming the mixed-phase metal silicide layer into the single-phase metal silicide layer comprises performing the third heat treatment at a higher temperature than the second heat treatment.

17. The method of claim 15, wherein:
the mixed-phase metal silicide layer has both a CoSi phase and a CoSi₂ phase; and
the single-phase metal silicide layer has a CoSi₂ phase.

18. The method of claim 8, wherein forming the at least one spacer comprises forming an insulation layer for at least one spacer in the at least one opening so that the insulation layer is on the mixed-phase metal silicide layer, and etching back the insulation layer to complete the at least one spacer.

19. The method of claim 9, wherein:
forming the second insulation layer pattern comprises forming a second insulation layer on the first insulation layer pattern and forming the at least one contact hole by etching the second insulation layer; and
forming the at least one spacer comprises forming an insulation layer for at least one spacer in the at least one contact hole so that the insulation layer is on the mixed-phase metal silicide layer, and etching back the insulation layer to complete the at least one spacer.

20. The method of claim 8, further comprising:
forming a phase change material pattern on the lower electrode contact.

21. A nonvolatile memory device comprising:
an insulation layer pattern including at least one opening on a substrate;
a vertical cell diode in the at least one opening;
a mixed-phase metal silicide layer, in which at least two phases coexist, on the vertical cell diode;
at least one spacer in at least one aperture and on the mixed-phase metal silicide layer; and
a lower electrode contact in the at least one aperture and surrounded by the at least one spacer.

22. The nonvolatile memory device of claim 21, further comprising:
a second insulation layer pattern on the insulation layer pattern including at least one contact hole.

23. The nonvolatile memory device of claim 21, wherein the at least one aperture is at least one opening.

24. The nonvolatile memory device of claim 22, wherein the at least one aperture is at least one contact hole.
